(19) United States
(12) Patent Application Publication
(10) Pub. No.: US 2024/0042923 A1
(43) Pub. Date: Feb. 8, 2024

(54) TRAILER TESTER

(71) Applicant: Michael HARRIS, Slidell, LA (US)

(72) Inventor: Michael HARRIS, Slidell, LA (US)

(21) Appl. No.: 18/230,116

(22) Filed: Aug. 3, 2023

Related U.S. Application Data
(60) Provisional application No. 63/395,082, filed on Aug. 4, 2022.

(51) Int. Cl. B60Q 1/30; G01R 31/44; G01R 31/66

(52) U.S. Cl. CPC B60Q 1/305; G01R 31/44; G01R 31/66

(57) ABSTRACT

The techniques described herein relate to a trailer tester. The trailer tester may include a tester plug configured to couple to a complementary trailer plug, a battery receiver configured to removably couple to, i.e., receive, a rechargeable battery pack, and a main body. The main body may include a plurality of switches. Each switch may include a positive terminal configured to be connected through the battery receiver to a positive voltage terminal of the rechargeable battery pack, a negative terminal configured to connect through the battery receiver to a negative voltage terminal of the rechargeable battery pack, and an output terminal configured to be connected to a signal light of the trailer through the tester plug.

### CROSS-REFERENCE TO RELATED APPLICATIONS

This non-provisional patent application claims the benefit of U.S. Provisional Application No. 63/395,082, filed on Aug. 4, 2022, which is fully incorporated herein by reference as if fully set forth herein.

### BACKGROUND

A trailer is a device for hauling material that may be towed by a tow vehicle. To provide road safety functions, trailers typically include a number of signal lights for providing information to motorists and pedestrians in the vicinity of the trailer. Typically, trailer signal lights may include braking lights, turn signal lights, and running lights, although trailers may include a number of other signal and utility lights. The lights provide information about the movement of the trailer (e.g., whether the vehicle and trailer are slowing down, braking and whether the vehicle and trailer are turning) as well as enhance the trailer's visibility on the road.

In most trailer configurations, the trailer lights are controlled by the tow vehicle. Specifically, the trailer lights are connected through a suitable electronic coupling to an electrical system of the tow vehicle. If the operator of the tow vehicle uses the tow vehicle's brakes, the tow vehicle supplies an electric signal through the electronic coupling causing the brake lights on the trailer to be illuminated. Similarly, when the operator of the tow vehicle activates a turn signal, the tow vehicle transmits a different electrical signal through the electronic coupling to cause the appropriate turn signal light on the trailer to be illuminated. During operation, the tow vehicle may transmit other electrical signals through the electronic coupling to cause the trailer running lights to become illuminated, or to otherwise modify or adjust the trailer lighting configuration.

### BRIEF DESCRIPTION OF THE DRAWINGS

FIG. 1 illustrates a perspective view of a possible embodiment of a trailer tester for testing a trailer lighting system (trailer plug, trailer cable and trailer lights).

FIG. 2 illustrates the electrical system of the trailer tester along with a battery that may be connected to the trailer tester.

FIG. 3 illustrates a trailer tester connected to a trailer when the trailer's lighting system is being tested using the trailer tester embodiment illustrated in FIG. 1.

FIG. 4 illustrates another embodiment of a trailer tester for testing a trailer's lighting system (trailer plug, trailer cable and lights).

FIG. 5 illustrates a trailer tester connected to a trailer when the trailer's lighting system is being tested using the trailer tester embodiment illustrated in FIG. 4.

FIG. 6 illustrates a first part of a flowchart of a method of using one possible embodiment of the invention.

FIG. 7 illustrates a second part to the flowchart in FIG. 6 for using the possible embodiment.

### DETAILED DESCRIPTION

To ensure proper operation of a trailer, it is necessary to perform routine maintenance and inspection on various components and systems of the trailer. In addition to routine maintenance of a trailer's mechanical systems, such as its tires, bearings, braking systems (if any), and the like, it is necessary to perform routine maintenance on the trailer's lighting system.

Typically, when performing trailer maintenance, a technician who wishes to test the trailer's lighting system is required to connect a suitably configured vehicle to the trailer so that all of the trailer's lighting system can be tested. The technician can then operate various control systems of the vehicle to determine whether the corresponding signal lights are illuminating on the trailer. This testing process can be burdensome. It requires that the technician first connect a suitable vehicle (e.g., a work truck) to the trailer, which requires carefully backing the vehicle into a correct position beside the trailer. When the vehicle is connected to the trailer, the technician must then operate certain control systems in the vehicle (e.g., by pressing the vehicle's brake pedal or operating a turn signal level) to test whether the appropriate lights on the trailer are properly illuminating. Testing brake lights may be particularly difficult as they may require the brake pedal in the vehicle to be pressed by a first technician while requiring a second technician to simultaneously confirm the brake lights on the end of the trailer have turned on. If the appropriate lights are not properly illuminating, the technician(s) may then diagnose the problem and make suitable repairs.

This process is time consuming. If a technician is performing inspections on a large number of trailers, the constant repositioning and coupling of the tow vehicle to each individual trailer so that trailer's lighting systems can be tested can greatly increase the amount of time required to perform necessary inspections.

To mitigate this problem, the present disclosure provides a convenient hand-held system, i.e., a trailer tester, for testing the operation of a trailer's lighting system. In place of a conventional vehicle, the trailer tester may be coupled directly to the electrical connection on a trailer to enable a technician to perform routine trailer system maintenance. A power source may be connected to the trailer tester that enables the trailer tester to selectively illuminate the various signal lights of the trailer. By operating a number of user selectable control inputs (e.g., buttons, toggles or switches), a technician can quickly test different combinations of signal lights on a trailer that is being inspected.

The present trailer tester, therefore, enables a technician to perform quicker testing of the lighting and electrical systems of a trailer without the hassle of connecting a vehicle to the trailer. In various embodiments, the power source of the trailer tester includes a removable and rechargeable battery pack, allowing the trailer tester to be portable. Additionally, in specific embodiments, the trailer tester may be configured to be coupled to a conventional removable power tool battery pack, thereby increasing the likelihood of the technician having access to a charged battery that may be coupled to the trailer tester for use with a trailer. As such, the trailer tester may not require an external power source or a specific type of battery in order to operate.

The preceding detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, or detailed description.

It should be understood that this invention is not limited in its application to the details of construction and the arrangement of components set forth in the preceding description or illustrated in the accompanying drawings. The invention is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items. Unless specified or limited otherwise, the terms “mounted,” “connected,” “supported,” and “coupled” and variations thereof are used broadly and encompass both direct and indirect mountings, connections, supports, and couplings. Further, “connected” and “coupled” are not restricted to physical or mechanical connections or couplings.

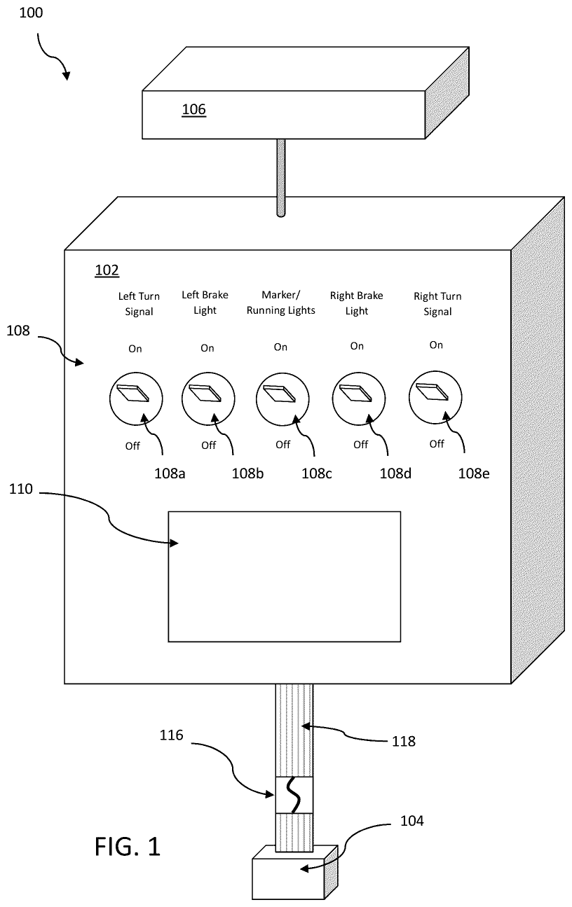

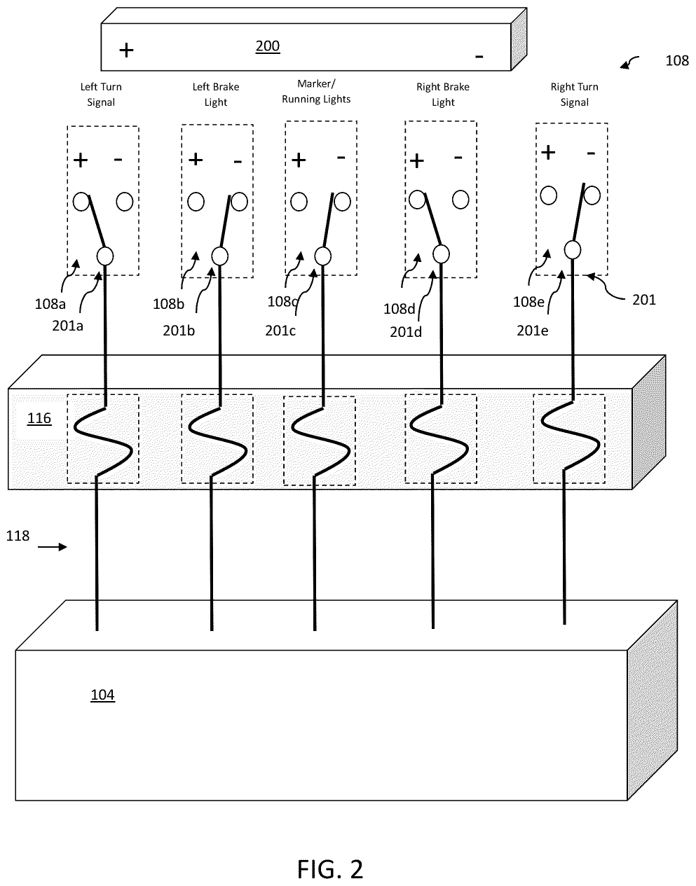

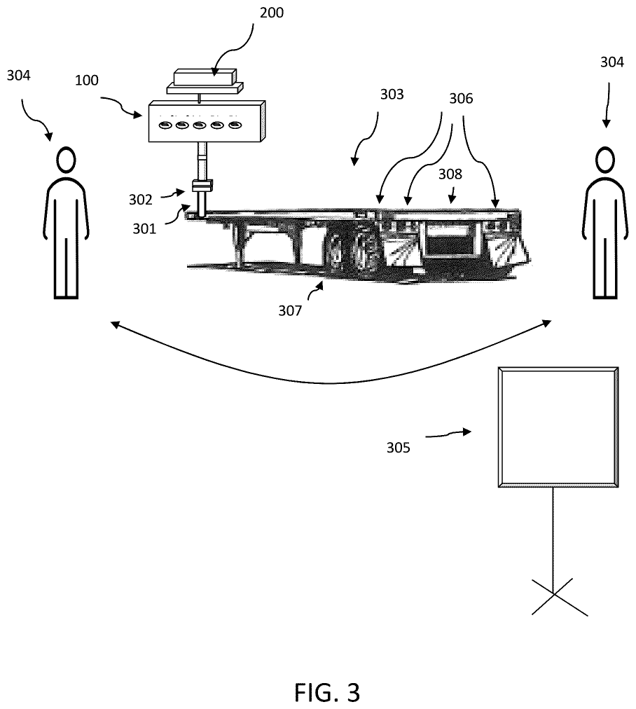

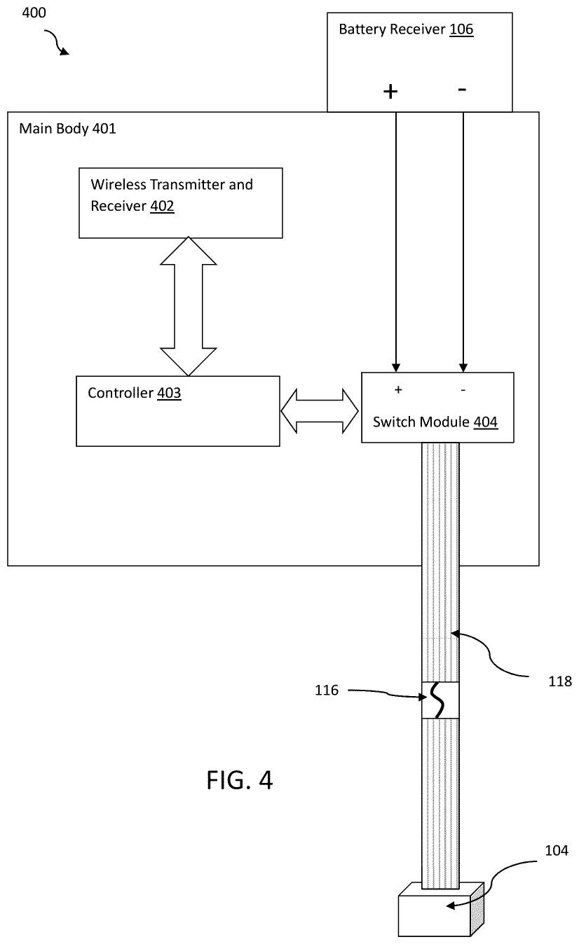

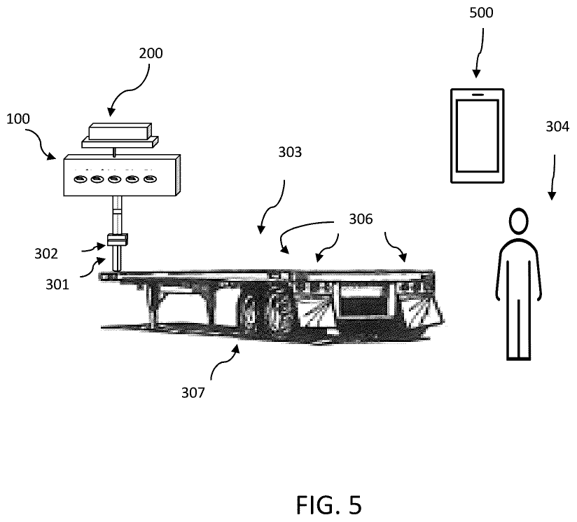

FIG. 1 illustrates a perspective view of a possible embodiment of a trailer tester 100 for testing a trailer's lighting system (trailer plug 302, trailer cable 301 and trailer lights 306). The trailer tester 100 is able to check for an electrical continuity of a trailer plug 302, a trailer cable 301 and a one or more lights on a trailer, i.e., trailer lights 306. FIG. 2 illustrates the electrical system of the trailer tester 100 along with a battery 200, preferably a rechargeable battery pack, that may be connected to the trailer tester 100. FIG. 3 illustrates a trailer tester 100 connected to a trailer 303 when the trailer's lighting system is being tested using the trailer tester 100 embodiment illustrated in FIG. 1. FIG. 4 illustrates another embodiment of a trailer tester 100 for testing a trailer's lighting system. FIG. 5 illustrates a trailer tester 100 connected to a trailer 303 when the trailer's lighting system is being tested using the trailer tester 100 embodiment illustrated in FIG. 4.

The trailer tester 100 includes a main body 102. The main body 102 may be connected to a tester plug 104 by a tester cable 118. Tester plug 104 may be configured to be coupled to a complementary plug (trailer plug 302) on the trailer 303 that is being tested. The trailer plug 302 may be connected to the trailer 303 and the trailer lights 306 by a trailer cable 301.

The tester plug 104 may comply with any desired format or protocol. The tester plug 104 may be, as non-limiting examples, a 4-way, 5-way, 6-way, 7-way, or any other type of plug or connector. Once the tester plug 104 is connected to a trailer 303, the tester plug 104 is configured to put components within the main body 102 in electronic communication with the trailer lights 306 on the connected trailer 303.

Battery receiver 106 may be coupled to the main body 102 by any desired means. As non-limiting examples, the battery receiver 106 may be connected to the main body 102 by a cable (shown in FIG. 1) or the battery receiver 106 may be built into the main body 102 as a single unit. The battery receiver 106 may be configured to be removably coupled or connected with any desired battery 200. As non-limiting examples, the battery 200 may be a portable rechargeable battery (e.g., a power tool battery, such as a MILWAUKEE brand xc5.0 or xc6.0 rechargeable battery pack) as a mechanism for providing electrical energy to components of the main body 102 and, ultimately, the trailer lights 306 on the trailer 303 being tested and that is connected to tester plug 104. The voltage of the battery 200 should match the voltage required for turning the trailer lights 306 on. As trailer lights 306 typically need 6, 12 or 24 volt to turn on (12 volt is the most common), it will typically be desirable for the battery 200 to be a 6, 12 (most common) or 24 volt battery 200.

As illustrated in FIG. 1 and FIG. 2, the main body 102 includes a number of switches 108a-108e. While any number of switches may be used, in a preferred embodiment, the number of switches matches a corresponding number of trailer lights 306 being tested. Thus, while FIG. 1 and FIG. 2 illustrate five switches, fewer or more switches may be used in the main body 102.

In another embodiment, the number of switches may be the maximum number of trailer lights 306 on any trailer 303 that is ever likely to be tested by the trailer tester 100. In this embodiment, extra switches 108 may be ignored for trailers 303 having fewer trailer lights 306 to test than the maximum number.

Each switch 108 is configured to electrically connect battery receiver 106 (and any power source or battery 200 connected thereto) to particular output pins of the tester plug 104. As such, when a removable rechargeable battery 200 is coupled to battery receiver 106 and tester plug 104 is connected to a trailer 303, switches 108 may be utilized to selectively supply electrical energy to various trailer lights 306 of a connected trailer 303 enabling a technician to test the trailer lights 306 on the trailer 303.

As a specific non-limiting example, with reference to FIG. 1 and FIG. 2, switch 108a may be configured to selectively supply electrical energy to the connected trailer's left turn signal via a first pin of tester plug 104. Switch 108b may be configured to selectively supply electrical energy to the connected trailer's left brake light via a second pin of tester plug 104. Switch 108c may be configured to selectively supply electrical energy to the connected trailer's marker or running lights via a third pin of tester plug 104. Switch 108d may be configured to selectively supply electrical energy to the connected trailer's right brake light via a fourth pin of tester plug 104. Switch 108e may be configured to selectively supply electrical energy to the connected trailer's right turn signal via a fifth pin of tester plug 104.

As illustrated by FIG. 2 each switch 108a-108e is connected at their respective positive voltage terminal to a positive voltage supply (e.g., provided by the battery 200 connected to battery receiver 106). Each switch 108a-108e is also connected at their respective negative voltage (ground) terminal to a negative (e.g., ground) voltage supply (e.g., provided by the battery 200 connected to battery receiver 106). Finally, the output terminal 201a-201e of each switch 108a-108e is connected by a separate wire to a particular pin of tester plug 104. When tester plug 104 is connected to a corresponding trailer plug 302 on a trailer 303, the pins are in electrical communication with a corresponding set of trailer lights 306 on the trailer 303. Further, the tester plug 104 may be configured to be physically and electrically connected to the trailer plug 302.

As an example, output terminal 201a is connected to the pin in tester plug 104 configured to electrically connect to the trailer's left turn signal light. Output terminal 201b is connected to the pin in tester plug 104 configured to electrically connect to the trailer's left brake light. Output terminal 201c is connected to the pin in tester plug 104 configured to electrically connect to the trailer's marker or running lights. Output terminal 201d is connected to the pin in tester plug 104 configured to be electrically connected to the trailer's right brake light. Output terminal 201e is connected to the pin in tester plug 104 configured to be electrically connected to the trailer's right turn signal.

In their default or ‘off’ positions, each of the switches 108 is configured so that there is an open circuit between the positive terminal and the output terminal 201 of the switch 108. As such, the output terminal 201 for each switch 108 in the default or ‘off’ position is not energized and will not cause the trailer lights 306 to illuminate. In addition, in some embodiments, in their default or ‘off’ positions, each of the switches 108 is configured so that there is a closed circuit between the negative terminal and the output terminal 201 of the switch 108. This further ensures that the output terminals 201 of the switches 108 are not energized and will not cause the trailer lights 306 to illuminate. Thus, each switch is capable of independently routing a positive or a negative electrical signal (ground) to a corresponding output post.

Further, in their active or ‘on’ positions, each of the switches 108 is configured so that there is a closed circuit between the positive terminal and the output terminal 201 of the switch 108. As such, the output terminal 201 for each switch 108 in the active or ‘on’ position is energized and will cause the trailer lights 306 to illuminate. In addition, in some embodiments, in their active or ‘on’ positions, each of the switches 108 is configured so that there is an open circuit between the negative terminal and the output terminal 201 of the switch 108. This further ensures that the output terminals 201 of the switches 108 are energized and will cause the trailer lights 306 to illuminate. Each of the plurality of switches 108 may be manually switched back and forth between providing a positive voltage corresponding to an ‘on’ position and a negative voltage, i.e., a ground corresponding to an ‘off’ position, to a corresponding light on the trailer 303.

It should be appreciated that this embodiment of the trailer tester 100 allows zero, one or more or all of the switches 108 to be ‘off’ at the same time. This embodiment of the trailer tester also allows zero, one or more or all of the switches to be ‘on’ at the same time. Thus, the trailer tester 100 may be set to any desired switch setting by the technician manually switching or flipping the switches to the desired switch setting. This flexibility helps the technician to quickly track down electrical problems even when the problems are caused by issues with multiple trailer lights 306.

In another embodiment, a switch 108 may be added to the trailer tester 100, 400 that either releases or engages a trailer brake system 307 on the trailer 303 being tested. The trailer brake system switch 108 may be electrically connected through the tester cable 118, tester plug 104, trailer plug 302, trailer cable 301 to the trailer brake system 307. The technician 304 may flip the trailer brake system switch 108 to apply either 0 volts (ground) to the trailer brake system 307 (releasing the brakes) or a desired voltage (typically 6, 12 or 24 volts) to the trailer brake system 307 (engaging the brakes). The technician 304 may then verify that the trailer brake system 307 has either released or engaged the trailer brake system 307 on the trailer 303. In some embodiments, the trailer brake system switch 108 may be a potentiometer or a variable resistor that allows the technician 304 to apply a range of voltages to the trailer brake system 307 to aid in trouble shooting possible problems with the trailer brake system 307.

In another embodiment, a single switch may be added to the trailer tester 100 that turns all of the trailer lights 306 on when in an ‘on’ position or all of the trailer lights 306 off when in an ‘off’ position. This greatly speeds the testing of the trailer lights 306 as the technician 304 only has to flip one switch in order to verify all of the trailer lights 306 are able to turn on and off.

In another embodiment of the trailer tester 100, a number of fuses 116 may be incorporated into the cable 118 that connects the main body 102 to the tester plug 104. In other embodiments a number of fuses may be placed inside the main body 102 of the trailer tester 100 inside a fuse box and electrically positioned between the switches and the tester cable 118 or the tester plug 104. The fuses 116 may be incorporated in-line to one or more of the wires making up the tester cable 118 to provide protection from potential electrical faults (e.g., electrical shorts) that may be present in one or more of the electrical systems of the trailer 303 being tested. In an embodiment, fuses 116 may be incorporated into select wires (e.g., the green, yellow, and brown wire) of the tester cable 118 to provide appropriate levels of electrical protection.

In another embodiment, the trailer tester 100, 400 may include a video screen 110 configured to display the output of a trailer's video camera system 308. The trailer's video camera system 308 may have a power supply, such as a battery, located on the trailer 303 or the trailer's video camera system 308 may receive power from the battery 200 connected to the trailer tester 100, 400 via the tester cable 118, tester plug 104, trailer plug 302 and the trailer cable 301. The video from the trailer's video camera system 308 may be wirelessly transmitted to the trailer tester 100 or wirelessly transmitted to a mobile electronic device 500, such as a cell phone, of the technician 304. In other embodiments, the video from the trailer's video camera system 308 may be routed through the trailer cable 301, trailer plug 302, tester plug 104 and tester cable 118 to the trailer tester 100, 400 where video from the trailer's video camera system 308 may be displayed on the video screen 110 to the technician 304.

To use the trailer tester 100, a technician 304 may first place each of the switches 108 into their ‘off’ positions. The technician 304 may then connect a charged battery 200 to the battery receiver 106 and connect the tester plug 104 to a compatible trailer plug 302 on a trailer 303. The technician 304 can then sequentially (or in any order and/or combination desired by the technician 304) toggle the positions of switches 108 to confirm that after turning each switch 108 to its ‘on’ position the corresponding trailer light 306 (or combination of trailer lights 306 if more than one switch is in the ‘on’ position) is properly illuminated on the trailer 303 being tested. If a trailer light 306 does not operate as anticipated, the technician 304 can diagnose the issue and make appropriate repairs.

FIG. 1 and FIG. 2 depict an embodiment of a trailer tester 100 configured in accordance with the present disclosure. FIG. 3 shows the trailer tester 100 of FIG. 1 and FIG. 2 coupled to a trailer 303. As depicted, the trailer tester 100 includes a main body 102 that includes a number of switches 108. A battery 200 is connected to a battery receiver 106. Trailer tester 100 includes a tester plug 104 enabling the trailer tester 100 to be electrically connected to the trailer lights 306. Once connected, an operator can selectively toggle switches 108 to supply electrical energy to the different trailer lights of the trailer 303 as part of a testing program.

Referring to FIG. 3, even with the improvements in the trailer tester 100 discussed so far, after toggling one or more of the switches, the technician 304 may still have to walk to the end of the trailer 303 (or use a second technician 304) to verify the current state of the trailer lights 306. In one possible embodiment, the tester cable 118 may be made a suitable length so that the technician 304 may stand at the back of the trailer 303 so that the technician 304 can toggle one or more of the switches and be in a position to see the trailer lights 306 at the same time. While the tester cable 118 may be any desired length, in certain embodiments the tester cable 118 may be 10 feet, 20 feet, 30 feet, 40 feet or longer to allow the technician 304 to toggle switches 108 on the trailer tester 100 while simultaneously (less than a second) watching the trailer lights 306.

In another possible embodiment, a mirror 305 may be placed behind the back of the trailer 303. This allows the trailer tester 100 to have a shorter tester cable 118, but still allows the technician 304 to toggle switches 108 while being able to simultaneously (less than a second) watch the trailer lights 306.

In another embodiment, the trailer tester 100, 400 may have another switch, button, etc. that puts the trailer tester 100, 400 into an automatic rotation mode. In this mode the trailer tester 100, 400 may automatically sequentially cycle through applying power to all of the trailer lights 306 one at a time for a predetermined length of time. In some embodiments, the trailer tester 100, 400 may have a speaker and announce which of the trailer lights 306 is currently being turned ‘on’ or ‘off’. The automatic rotation mode allows the technician 304 to connect the trailer tester 100, 400 near the front of the trailer 303 (where the trailer cable 301 and trailer plug 302 are generally connected/located) and then walk to the back of the trailer 303 and determine which of the trailer lights 306 are working or not working.

FIG. 4 and FIG. 5 illustrate another embodiment of the invention that allows the technician 304 to toggle switches 108 while standing in a position to simultaneously (hereby defined to be less than a second) see the trailer lights. In this embodiment, the trailer tester 400 may have a transmitter and receiver 402. The transmitter and receiver 402 may be paired with or be able to communicate with a mobile electronic device 500. The mobile electronic device 500 may be a laptop, cell phone or any other suitable small portable electronic device. The trailer tester 400 may also have a controller 403. The controller 403 may be, as non-limiting examples, a microprocessor, microcontroller unit (MCU) or embedded controller, that is able to communicate with the technician 304 via the transmitter and receiver 402. The trailer tester 400 may also have a switch module 404 that is controllable by the controller 403 and that functions as a plurality of switches 108. The switch module 404 may have a positive electrical input and a negative electrical input configured to be electrically connected to a positive terminal and a negative terminal respectively of a battery 200. In some embodiments, the trailer tester 400 may also allow the switches 108 in the switch module 404 to be controlled by external buttons or flip switches on the outer surface of the trailer tester 400. The trailer tester 400 may also have a battery receiver 106 that may receive a battery 200 to supply the electrical energy that powers the trailer lights 306. In this embodiment, the trailer tester 400 may either use the battery 200 to power the wireless transmitter and receiver 402, controller 403 and switch module 404 or the trailer tester 400 may have its own separate battery power supply. The wireless transmitter and receiver 402, controller 403 and switch module 404 may be protectively housed in a main body 401.

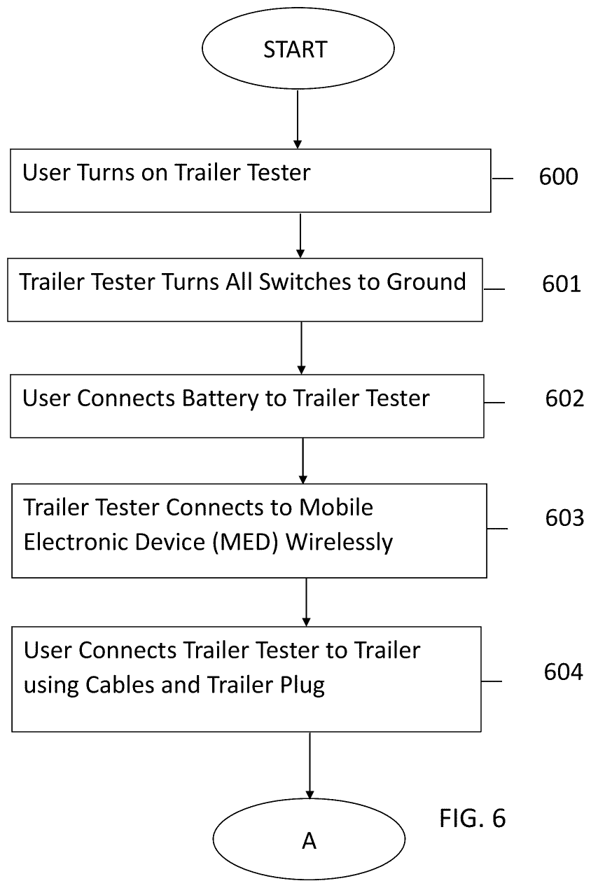

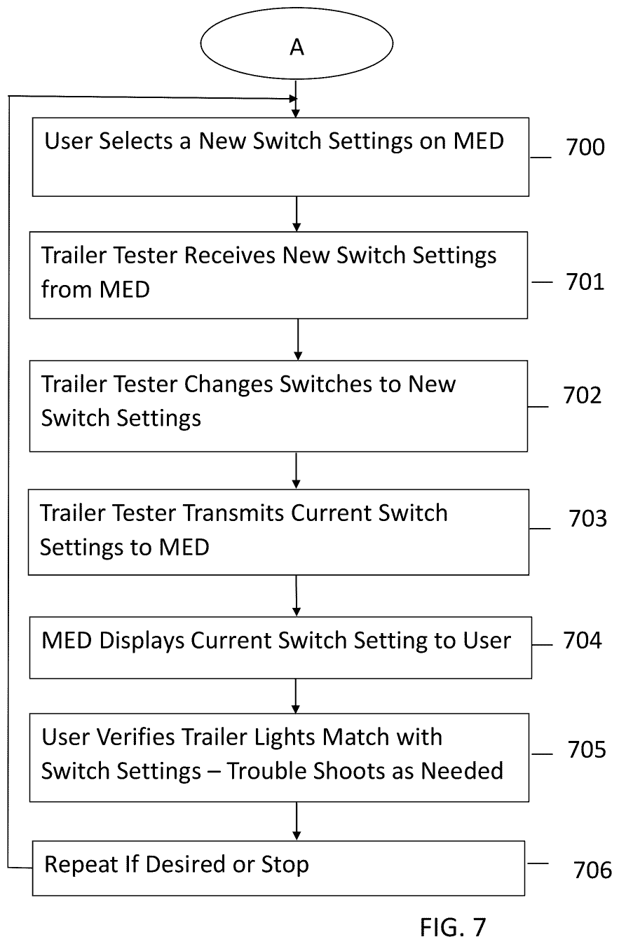

FIG. 6 and FIG. 7 illustrate a flowchart of a process that may use the trailer tester 400 shown in FIG. 4 and FIG. 5 to test the trailer lights 306 of a trailer 303. The technician 304 (user) may turn the trailer tester 400 on. (Step 600) If the trailer tester 400 gets its power from a battery 200, the trailer tester 400 may be turned on after being connected to the battery 200. (Step 602) Once the trailer tester 400 is turned on, the trailer tester 400 may automatically set all of the switches to either an open position or set all of the switches to a ground position. (Step 601)

The technician 304 may then connect or pair (possibly using the Bluetooth protocol or any other desired protocol) the trailer tester 400 with the mobile electronic device 500 in a wireless manner. (Step 603) The technician 304 may then connect the tester plug 104 with the trailer plug 302. (Step 604) The mobile electronic device 500 may run an application or other software or firmware program that allows the technician 304 to 1) see the current switch settings of the switches 108 (Step 704) and/or 2) allows the technician 304 to select a new switch setting (Step 700). The transmitter and receiver 402 of the trailer tester 400 may from time to time receive new switch settings from the technician 304 using the mobile electronic device 500. (Step 701) The transmitter and receiver 402 may communicate the new switch setting to the controller 403. The controller 403 may then communicate the new switch setting to the switch module 404. The switch module 404 may then alter the switches 108 as needed to match the received new switch setting. (Step 702) The trailer tester 100 may transmit the current switch setting to the mobile electronic device 500 to confirm the current switch setting to the technician 304. (Step 703) The technician 304 may then verify whether or not the trailer lights 306 on the trailer 303 being tested match the current switch setting displayed on the mobile electronic device 500. (Step 705) The technician 304 may then use this information and take appropriate actions accordingly. It should be appreciated that the technician 304 may change the switch setting any number of times as desired by the technician 304. (Step 706) It should also be appreciated that many of the steps may be performed in a different order unless logically or physically impossible.

The preceding discussion is presented to enable a person skilled in the art to make and use embodiments of the invention. Various modifications to the illustrated embodiments will be readily apparent to those skilled in the art, and the generic principles herein can be applied to other embodiments and applications without departing from embodiments of the invention. Thus, embodiments of the invention are not intended to be limited to embodiments shown, but are to be accorded the widest scope consistent with the principles and features disclosed herein. The preceding detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the invention.

The connecting lines shown in the various figures contained herein are intended to represent exemplary functional relationships and/or physical couplings between the various elements. It should be noted that many alternative or additional functional relationships or physical connections may be present in an embodiment of the subject matter. In addition, certain terminology may also be used herein for the purpose of reference only, and thus are not intended to be limiting, and the terms “first”, “second” and other such numerical terms referring to structures do not imply a sequence or order unless clearly indicated by the context.

The foregoing description refers to elements or nodes or features being “connected” or “coupled” together. As used herein, unless expressly stated otherwise, “connected” means that one element is directly joined to (or directly communicates with) another element, and not necessarily mechanically. Likewise, unless expressly stated otherwise, “coupled” means that one element is directly or indirectly joined to (or directly or indirectly communicates with, electrically or otherwise) another element, and not necessarily mechanically. Thus, although the schematic shown in the figures depict one exemplary arrangement of elements, additional intervening elements, devices, features, or components may be present in an embodiment of the depicted subject matter.

In some aspects, the techniques described herein relate to a trailer tester, including: a tester plug configured to couple to a complementary plug on a trailer; a battery receiver configured to removably couple to a rechargeable battery pack; and a main body, including: a plurality of switches, wherein each switch includes a positive terminal configured to connect through the battery receiver to a positive voltage terminal of the rechargeable battery pack, a negative terminal configured to connect through the battery receiver to a negative voltage terminal of the rechargeable battery pack, and an output terminal configured to connected to a signal light of the trailer through the trailer plug.

In some aspects, the techniques described herein relate to a trailer tester, wherein a first output terminal of a first switch of the plurality of switches is configured to connect to a left turn signal light of the trailer through the trailer plug.

In some aspects, the techniques described herein relate to a trailer tester, wherein a second output terminal of a second switch of the plurality of switches is configured to connect to a left brake light of the trailer through the trailer plug.

In some aspects, the techniques described herein relate to a trailer tester, wherein a third output terminal of a third switch of the plurality of switches is configured to connect to a running light of the trailer through the trailer plug.

In some aspects, the techniques described herein relate to a trailer tester, wherein a fourth output terminal of a fourth switch of the plurality of switches is configured to connect to a right brake light of the trailer through the trailer plug.

In some aspects, the techniques described herein relate to a trailer tester, wherein a fifth output terminal of a fifth switch of the plurality of switches is configured to connect to a right turn signal of the trailer through the trailer plug.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A trailer tester for testing a trailer plug, a trailer cable and one or more lights on a trailer, comprising:
a tester plug configured to be physically and electrically connected to the trailer plug;
a battery receiver configured to be removably coupled to a rechargeable battery pack; and
a main body, including:
a plurality of switches, wherein each switch includes a positive terminal configured to be connected through the battery receiver to a positive voltage terminal of the rechargeable battery pack, a negative terminal configured to be connected through the battery receiver to a negative voltage terminal of the rechargeable battery pack, and an output terminal configured to be electrically connected to one of the one or more lights on the trailer through a tester cable and the tester plug.

2. The trailer tester of claim 1, wherein a first output terminal of a first switch of the plurality of switches is configured to be electrically connected to a left turn signal light of the trailer through the tester plug.

3. The trailer tester of claim 2, wherein a second output terminal of a second switch of the plurality of switches is configured to be electrically connected to a left brake light of the trailer through the tester plug.

4. The trailer tester of claim 3, wherein a third output terminal of a third switch of the plurality of switches is configured to be electrically connected to a running light of the trailer through the tester plug.

5. The trailer tester of claim 4, wherein a fourth output terminal of a fourth switch of the plurality of switches is configured to be electrically connected to a right brake light of the trailer through the tester plug.

6. The trailer tester of claim 5, wherein a fifth output terminal of a fifth switch of the plurality of switches is configured to be electrically connected to a right turn signal of the trailer through the tester plug.

7. The trailer tester of claim 1, wherein each of the plurality of switches may be manually switched back and forth between providing a positive voltage or a ground to a corresponding light on the trailer.

8. A trailer tester, comprising:
a tester plug that is connected to a tester cable that is connected to the trailer tester, configured to be physically and electrically connected to a trailer plug that is connected to a trailer cable that is connected to a trailer;
a battery receiver configured to be removably coupled to a rechargeable battery pack; and
a main body, including:
a wireless transmitter and receiver configured to be able to wirelessly communicate with a mobile electronic device;
a switch module comprising:
a positive electrical input configured to be electrically connected to a positive terminal of the rechargeable battery pack;
a negative electrical input configured to be electrically connected to a negative terminal of the rechargeable battery pack; and
a plurality of switches, wherein each switch is capable of independently routing a positive or a negative electrical signal to a corresponding output post; and
a controller in electrical communication with the wireless transmitter and receiver and in electrical communication with the switch module.

9. The trailer tester of claim 8, wherein the wireless transmitter and receiver is configured to wirelessly receive a new switch setting from the mobile electronic device.

10. The trailer tester of claim 9, wherein the controller is configured to receive the new switch setting from the wireless transmitter and receiver.

11. The trailer tester of claim 10, wherein the controller is configured to transmit the new switch setting to the switch module.

12. The trailer tester of claim 11, wherein the switch module is configured to alter the plurality of switches to match the new switch setting.

13. The trailer tester of claim 8, wherein the controller is configured to receive a current switch setting from the switch module.

14. The trailer tester of claim 13, wherein the controller is configured to communicate the current switch setting to the wireless transmitter and receiver.

15. The trailer tester of claim 14, wherein the wireless transmitter and receiver is configured to transmit the current switch setting to the mobile electronic device.

16. The trailer tester of claim 8, further comprising a fuse box electrically connected within the tester cable.

17. A method of checking an electrical continuity of a trailer plug, a trailer cable and a one or more lights on a trailer with a trailer tester, comprising steps of:
receiving by a wireless transmitter and receiver a new switch setting from a mobile electronic device;
receiving by a controller the new switch setting from the wireless transmitter and receiver;
receiving by a switch module, comprising a plurality of switches, the new switch setting from the controller; and
switching by the switch module at least one switch in the plurality of switches so that the plurality of switches match the new switch setting.

18. The method of claim 17, further comprising a step of:
receiving by the controller a current switch setting from the switch module.

19. The method of claim 18, further comprising a step of:
communicating by the controller the current switch setting to the wireless transmitter and receiver.

20. The method of claim 19, further comprising a step of:
transmitting by the wireless transmitter and receiver the current switch setting to the mobile electronic device.
